(19) United States
(12) Patent Application Publication
(10) Pub. No.: US 2004/0061167 A1
(43) Pub. Date: Apr. 1, 2004

(54) Method of improving erase efficiency and a non-volatile memory cell made thereby

(76) Inventor: Bhaskar Mantha, Pleasanton, CA (US)

Correspondence Address: GRAY CARY WARE & FREIDENRICH LLP, 2000 UNIVERSITY AVENUE, E. PALO ALTO, CA, 94303-2248, US

(21) Appl. No.: 10/263,004

(22) Filed: Oct. 1, 2002

(51) Int. Cl. H01L 29/788

(52) U.S. Cl. 257/315

(57) ABSTRACT

Erase efficiency in a non-volatile memory cell can be increased by lowering the work function of the material from which the electrons emanate traversing the insulating layer. In particular, the conventional polysilicon/oxide/polysilicon mechanism can be replaced by a silicide/oxide/polysilicon mechanism to either increase the current density of erasure, thereby decreasing erase time, or by lowering the applied voltage for the same erase time.

### TECHNICAL FIELD

The present invention relates to a method and an apparatus for improving the erase efficiency of charges traversing between two regions through an insulating layer, and more particularly the present invention relates to an improved non-volatile memory cell made thereby.

### BACKGROUND OF THE INVENTION

Non-volatile memory cells using a floating gate to store charges thereon to control the conduction of charges in a channel are well known in the art. Typically, the floating gate is programmed by either injecting electrons onto the floating gate through hot channel electron or through Fowler-Nordheim tunneling of the electrons to the floating gate. The electrons are removed from the floating gate or are erased by the mechanism of Fowler-Nordheim tunneling from the floating gate to either another gate, such as a control gate, or to the substrate or even to a source or drain region in the substrate.

Non-volatile memory cells of the floating gate type generally fall into one of two types: split gate or stack gate. In a split gate non-volatile floating gate memory cell, the floating gate is insulated from the channel and controls a portion of the conduction in the channel. A control gate is laterally spaced apart from the floating gate and controls another portion of the conduction in the channel. The mechanism of erasure is from the floating gate through the insulation separating the floating gate from the control gate to the control gate. This type of cell is exemplified by U.S. Pat. No. 5,029,130 whose disclosure is incorporated by reference herein. Other erase mechanisms include the Fowler-Nordheim tunneling of electrons from the floating gate to the substrate (channel region), or the sour/drain region in the substrate, or even to another gate.

In a stack gate type of non-volatile memory floating gate cell, the control gate is “on top” of the floating gate. The floating gate controls the conduction of the entire channel in a substrate. The control gate is positioned “above” the floating gate and provides capacitive coupling therewith. Typically, the floating gate is erased by having electrons tunnel from the floating gate through an insulation into the substrate or the source/drain region in the substrate. Of course, erasure can also occur by Fowler-Nordheim tunneling of charge from the floating gate to the control gate, or another gate. An example of a stack gate is U.S. Pat. No. 4,698,787 whose disclosure is also incorporated herein by reference.

Typically, in the Fowler-Nordheim tunneling of electrons from the floating gate to either a control gate or the substrate or a region of the memory cell, a charge pump must be used to pump up the externally supplied voltage to a “high” voltage which is sufficient to cause the Fowler-Nordheim tunneling of electrons. A charge pump takes up valuable real estate on an integrated semiconductor silicon chip. Further, the use of high voltage requires high voltage isolations which takes up additional valuable real estate on the silicon chip. Finally, the use of high voltage can cause spurious noise and the like on other parts of the circuit. In addition, the mechanism of Fowler-Nordheim tunneling is slow. Therefore, it is desired to increase the efficiency of the erase operation by either lowering the high voltage required and/or increasing the current density for the erase mechanism. This would result in reducing the time required for erasure.

### SUMMARY OF THE INVENTION

In the present invention a method of improving erase efficiency in a non-volatile memory cell between a floating gate from which electrons are to be removed through an insulating material to a region in the cell thereby erasing the floating gate has the region made of a first material having a first work function. The method comprises providing a second material to the floating gate immediately adjacent to the insulating material. The second material has a second work function lower than the first work function (before the two materials are joined together) and is a material from which electrons from the floating gate traverse the insulating material to the region.

The present invention also provides a non-volatile semiconductor memory cell having a floating gate in which electrons are stored and from which electrons are removed through an insulating material to a region in the cell thereby erasing the floating gate. The region is of a first material having a first work function. The improvement to the memory cell comprises the floating gate having a second material having a second work function lower than the first work function (before the two materials are joined together) and is positioned immediately adjacent to the insulating material. The second material is a material from which electrons from the floating gate traverse through the insulating material to the region.

### BRIEF DESCRIPTION OF THE DRAWINGS

FIG. 1 is a cross-sectional view of one embodiment of a split gate non-volatile floating gate memory cell of the present invention.

FIGS. 2a-2g are cross-sectional views of different steps used in the method of making the memory cell shown in FIG. 1.

FIG. 3 is a cross-sectional view of another embodiment of a split gate non-volatile floating gate memory cell of the present invention.

FIG. 4a-4g are cross-sectional views of different steps used in the method of making the memory cell shown in FIG. 3.

FIG. 5 is a cross-sectional view of one embodiment of a stack gate non-volatile floating gate memory cell of the present invention.

FIG. 6a-6b are cross-sectional views of different steps used in the method of making the memory cell shown in FIG. 5.

FIG. 7 is a cross-sectional view of another embodiment of a stack gate non-volatile floating gate memory cell of the present invention.

FIG. 8a-8b are cross-sectional views of different steps used in the method of making the memory cell shown in FIG. 7.

FIG. 9 is a graph showing the calculated voltage versus current density is applicable to a non-volatile floating gate memory cell of the present invention versus the memory cell of the prior art.

FIG. 10 is a graph showing calculated relationship between J/E2 and 1/E (Fowler-Nordheim Characteristics) in a non-volatile floating gate memory cell of the present invention versus the memory cell of the prior art.

### DETAILED DESCRIPTION OF THE INVENTION

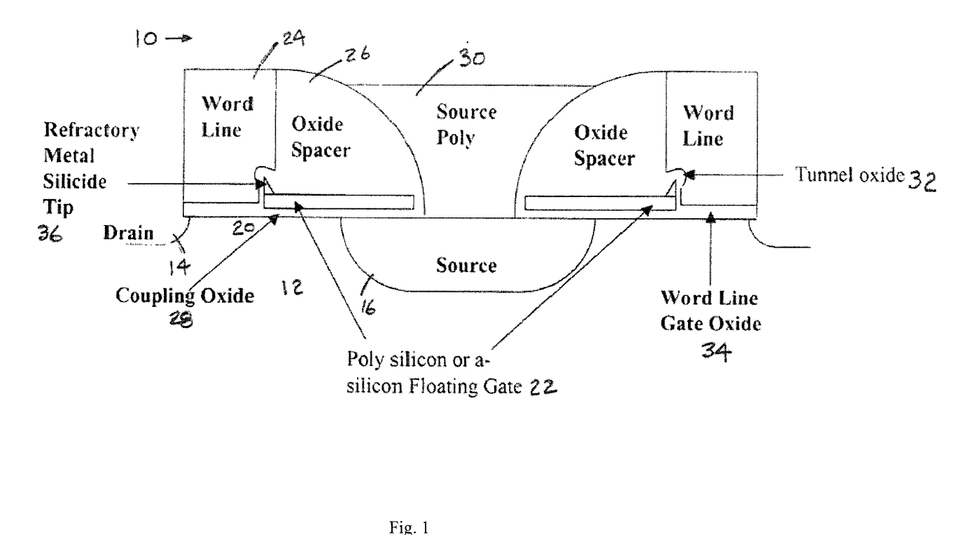

Referring to FIG. 1, there is shown a cross-sectional view of one embodiment of a split gate floating gate memory cell 10 of the present invention. The memory cell 10 comprises a semiconductor silicon substrate 12 having a first region 14 and a second region 16 spaced apart from one another by a channel region 20. The first region 14 and the second region 16 are of a first conductivity type while the channel region 20 is of a second conductivity type. Although the first region 14 and the second region 16 are labeled as drain and source respectively, it should be understood that the terms are interchangeable and are not so limited. Spaced apart from the substrate 12 is a polysilicon or amorphous silicon floating gate 22. The floating gate 22 is insulated from the substrate 12 by a coupling oxide 28. The coupling oxide 28 can be silicon oxide or silicon dioxide (hereinafter collectively referred to as “silicon (di)oxide”) or any other type of insulating material, including but not limited to silicon nitride or a composite material such as ONO. The floating gate 22 is positioned such that it overlies a first portion of the channel region 20 and a first portion of the second region 16. The floating gate 22 also comprises a refractory metal silicide tip 36 whose function will be explained in greater detail hereinafter. Spaced apart from the floating gate 22 is a control gate or word line 24. The word line 24 is separated and insulated from the floating gate 22 and in particular from the refractory metal silicide tip 36 by a tunnel oxide region 32. Again the tunnel oxide region 32 can be any type of insulating material, although in the preferred embodiment it is silicon (di)oxide. In addition, the word line 24 is separated or insulated from the substrate 12 by a word line gate oxide region 34. An oxide spacer 26 is positioned “above” the floating gate 22. Finally, a polysilicon source 30 is electrically and physically connected to the second region 16.

With the exception of the refractory metal silicide tip 36, all of the components described hereinabove are well known in the art and are disclosed in U.S. Pat. No. 5,029,130, whose disclosure is incorporated herein by their reference. Further, as disclosed in the '130 patent, the operation of the memory cell 10 is also well known. In particular, to program the memory cell 10, or to inject electrons onto the floating gate 22, electrons are generated at the drain 14, and are accelerated towards the source 16 traversing along the channel 20. The word line 24 is activated so that it “turns on” the portion of the channel 20 above which the word line 24 is positioned. When the electron reaches the junction in the channel 20 between the word line 24 and the floating gate 22, it senses an abrupt change in voltage in the floating gate 22 which is capacitively coupled to the voltage applied to the source 16. It is then injected through the coupling oxide 28 and onto the floating gate 22. During the erase operation, the word line 24 is connected to a very high voltage source while the drain region 14 and the source region 16 are grounded. Electrons on the floating gate 22 tunnel through the mechanism of Fowler-Nordheim tunneling from the refractory metal silicide tip 36 through the tunnel oxide 32 onto the word line 24. The tip 36 is immediately adjacent to the tunnel oxide 32 and provides enhanced tunneling of the electrons from the floating gate 22 to the word line 24. Typically, the word line 24 is also made of polysilicon or amorphous silicon. On the other hand, the tip 36 is of a refractory metal silicide material such as tungsten silicide, or cobalt silicide. The use of a metal silicide material as one “gate” to be the source from which electrons tunnel through the tunnel oxide 32 onto the word line 24 greatly improves the efficiency of the erase operation, as will be discussed hereinafter.

The formation of the memory cell 10 shown in FIG. 1 can be done as follows. A substrate 12 which is of P type is the initial starting material. The first step is removal of native oxide by etching in buffered HF (NH4F+HF+H2) with surfactants followed by RCA clean, which is a solution of mixture of water, ammonium hydroxide and hydrogen peroxide (5:1:1 by volume) maintained at 80C. RCA clean removes organic and metallic contaminants from the surface of wafers of a p-type substrate 12. Thereafter, a layer of coupling oxide 28 is thermally grown on the substrate 12. The layer is approximately 80A thick. This is followed by the deposition of polysilicon or amorphous silicon 22 which would eventually form the floating gate 22. The polysilicon or amorphous silicon is deposited to a thickness of approximately 500A. This can be done by chemical vapor deposition (CVD). Chemical vapor deposition of polysilicon silicon is usually done by thermal decomposition of Silane (SiH4) in a Low Pressure CVD reactor (pressures are typically between 0.25 to 2 torr at temperatures between 600C and 650C). Amorphous silicon films are formed below 575C.

An implant step follows in which arsenic or phosphorus is implanted into the polysilicon or amorphous silicon layer 22. This can be done by an implant dose of 1.0E15 to 2.0E15/cm2 at 3 Kev. This low energy is chosen so that the implant does not penetrate in to the substrate. The implanted floating gate layer 22 is annealed at 900C for about 30 minutes in nitrogen in order to distribute arsenic or phosphorus uniformly. A rapid thermal anneal step at a temperature of 950 to 1000C for 20 to 30 seconds may also be useful. Another way to dope the floating gate is by in-situ doping by phosphorus (to a concentration of 1.0 to 2.0E20/cm3) by introducing phosphine gas during deposition of the floating gate. A thin (200-300A) layer of refractory metal silicide (examples of silicide layers are titanium silicide, cobalt suicide, tungsten silicide) 36 is deposited by low pressure chemical vapor deposition over the floating gate 22. Chemical vapor deposition of refractory metal deposition is done by reacting refractory metal chlorides or fluorides with silane at temperatures of 300C to 400C and pressures of 50 to 300 mtorr. Another method is to react refractory metal chlorides or fluorides with dichlolosilane. The refractory metal silicide layer would eventually form the tip 36. Another way of forming about 200A to 300A refractory metal silicide is to sputter deposit 50A to 70A refractory metal over previously implanted or in-situ doped floating poly silicon or amorphous silicon after 1 minute etch in dilute HF (100:1 by volume of H2O:HF).

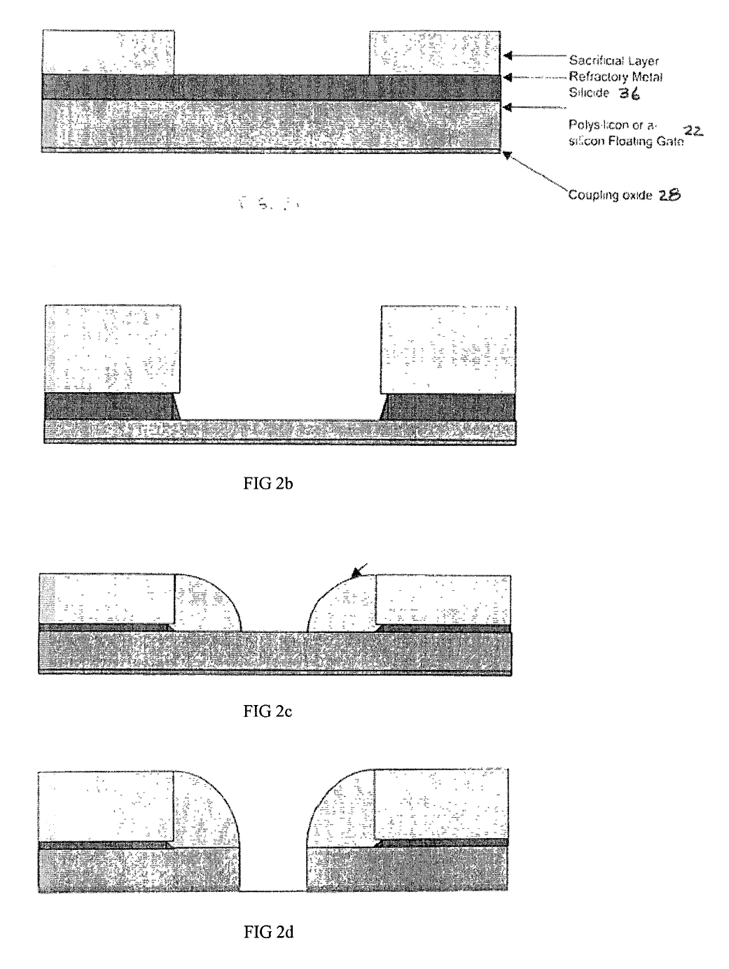

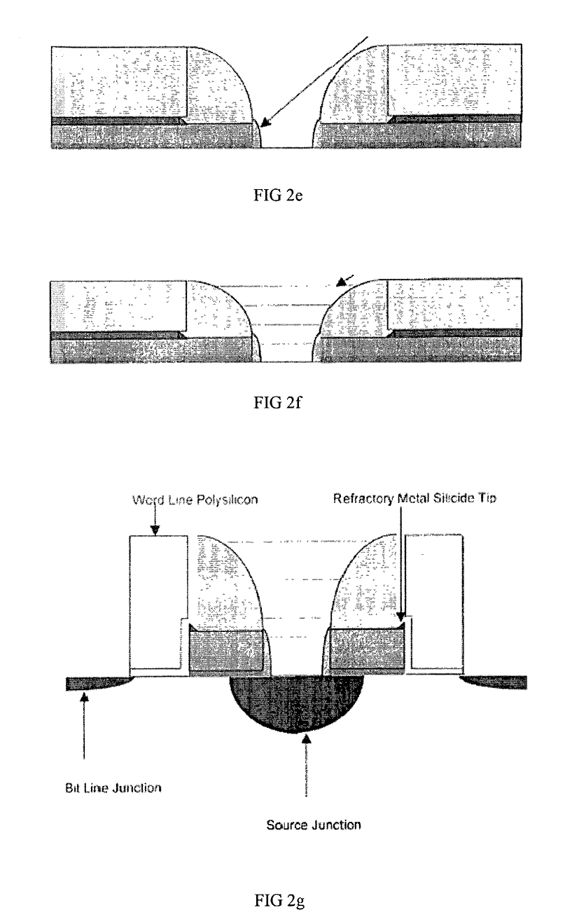

RTP anneal step is carried out at 700 to 800C for 30 to 40 seconds in an argon or nitrogen ambient. A conventional shallow trench isolation process module processing follows. This shallow trench isolation process module forms the isolation between columns of memory cells 10. A layer of sacrificial dielectric film is deposited on the structure. The dielectric film is silicon nitride having a thickness of 4000A. This can be formed by LPCVD by reacting silane or dichlorosilane with ammonia at temperatures between 700C and 800C. A photoresist coating and mask exposure follows. The photoresist is developed and is used to etch the sacrificial dielectric in portions not covered by the photoresist coating. The resultant cross-sectional view is shown in FIG. 2a.

Using the sacrificial layer of dielectric as a mask layer, the refractory metal silicide 36 is slope etched. Fluorine based gases such as C2F6, CHF3, SF6, CF4 individually or combination of two or more gases can be used as plasma etch gases. Fluorine etches suicides isotropically. Plasma etch process optimization is required in order to get correct profile. After the refractory metal silicide layer 36 is etched, the resultant cross-sectional view is shown in FIG. 2b.

Spacer oxide is deposited everywhere followed by RIE etch back of the spacer oxide to form spacers adjacent to the sacrificial layer. The resultant structure is shown in FIG. 2c. Using the oxide spacer as a mask, the polysilicon or the amorphous silicon layer 22 is etched using RIE or other anisotropic etch method. The resultant cross-sectional view is shown in FIG. 2d.

A thin layer of thermal oxide is then grown to a thickness of approximately 50A, by rapid thermal oxidation at 950C for 40 to 50 seconds in an oxygen ambient. A thin layer of silicon dioxide of the order of 150A is deposited by LPCVD. The layer of deposited oxide is anisotropically etched resulting in oxide spacers being formed adjacent to the polysilicon or amorphous silicon layer 22. The resultant structure is shown in FIG. 2e.

Implants are done to form the source region 16. This is done by a combination of arsenic and phosphorus implants. This is followed by an anneal process for the source implants. The anneal is done at 900C for 30 minutes in nitrogen. This is followed by HF preclean, which is 1 minute etch in dilute HF (100:1 by volume of H2O:HF). In-situ doped source poly 30 is then deposited. The source poly 30 is then etched back. The resultant structure is shown in FIG. 2f.

The source poly is then oxidized. The sacrificial dielectric film first deposited and shown in FIG. 2a is then stripped in hot phosphoric acid maintained at 80 to 1000C. The refractory metal silicide 36 and the polysilicon or amorphous silicon forming the floating gate 22 are then etched. A thin thermal oxide is then grown. A tunnel oxide 32 is then deposited by CVD. This is followed by tunnel oxide densification. The word line poly is then deposited by CVD of polysilicon. The word line poly 24 is then implanted using the word line poly implant as the mask. This is followed by the implant step and the resist is then stripped away. The word line poly is then implanted with phosphorus and annealed. The word line spacer is then etched back. A bit line junction implant mask is used to implant bit line junction implant. The resist is stripped and the structure is annealed. The resultant structure is shown in FIG. 2g. With the exception of the steps for the formation of the metal silicide tip 36, all of the other steps for the formation of the memory cell 10 are well known in the art.

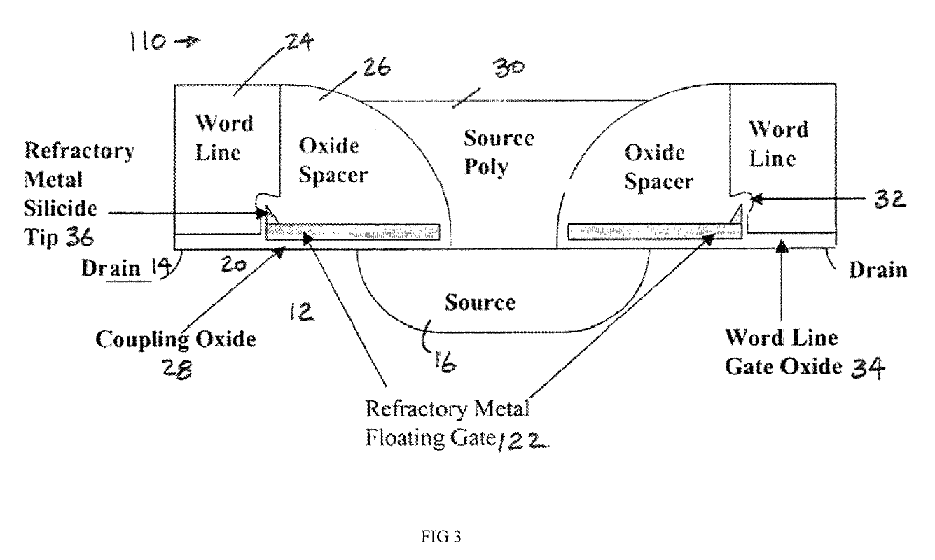

Referring to FIG. 3, there is shown another embodiment of a memory cell 110 of the present invention. The memory cell 110 is very similar to the memory cell 10 shown in FIG. 1. Thus, it has all of the same elements shown in FIG. 1 such as a substrate 12, spaced apart regions 14 and 16 and channel region 20. In addition, the memory cell 110 has the coupling oxide 28 over which a floating gate 122 lies. The floating gate 122 has a refractory metal silicide tip 36. In addition, the memory cell 110 has a polysilicon word line 24 with an oxide spacer 26 and a source poly 30 electrically connected to the source 16. The word line 24 is separated from the refractory metal silicide tip 36 by the tunnel oxide 32. The only difference between the memory cell 110 and the memory cell 10 is that the floating gate 122 is also of a refractory metal silicide material, unlike the floating gate 22 shown in FIG. 1 which is only of polysilicon or amorphous silicon material.

A method for manufacturing the memory cell 110 is identical to the method of forming the memory cell 10, except that the step of forming the refractory metal floating gate, such as tungsten, titanium or cobalt silicide is carried out by either CVD of the metal silicide or by sputter deposition of refractory metal and RTA of the film in nitrogen or argon. Thus one process for the formation of the memory cell 110 can be as follows.

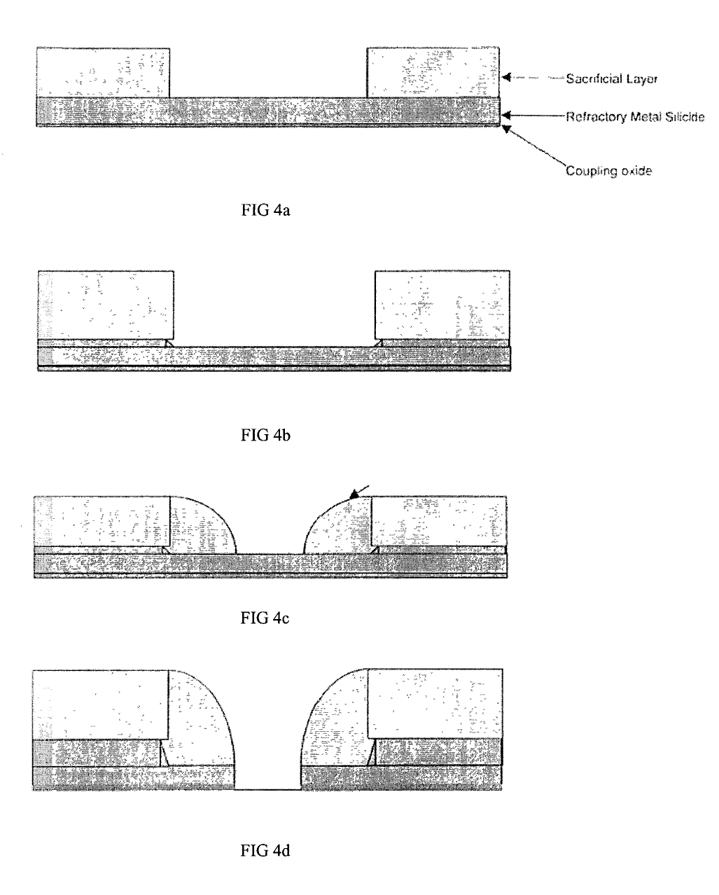

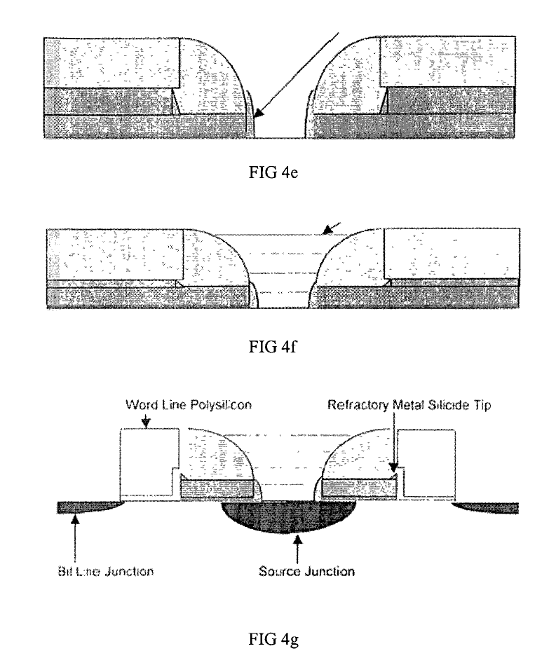

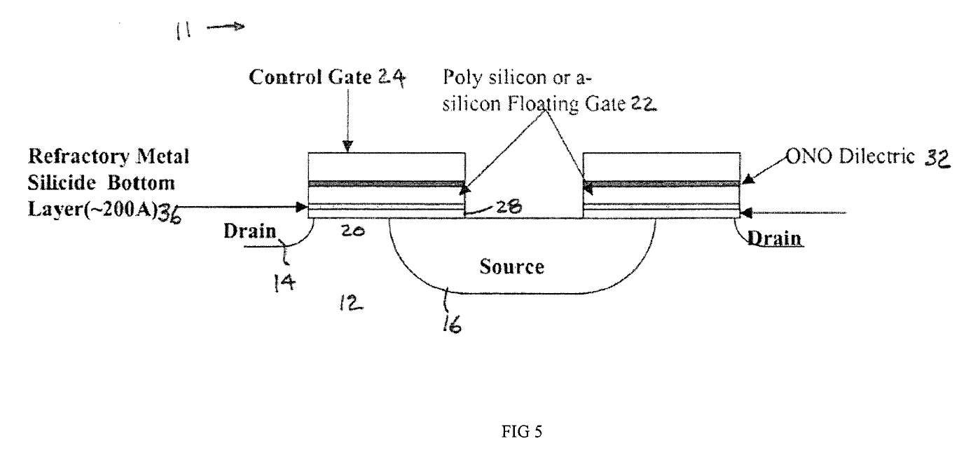

A substrate 12 which is of P type is the initial starting material. The first step is The first step is removal of native oxide by etching in buffered HF (NH4F+HF+H2) with surfactants followed by RCA clean of a p-type substrate 12. Thereafter, a layer of coupling oxide 28 is thermally grown on the substrate 12. The layer is approximately 80A thick. This is followed by the deposition of refractory metal silicide which would eventually form the floating gate 122. This can be done by CVD by reacting refractory metal chlorides or fluorides with silane at temperatures of 300C to 400C and pressures of 50 to 300 mtorr. Another method is to react refractory metal chlorides or fluorides with dichlolosilane. Another method of forming 800A refractory metal silicide is to sputter deposit 200A to 300A refractory metal over previously implanted (phosphorus, 1.0E15 to 2.0E15, 3 KeV) or in-situ doped (phosphorus, 1.0E20 to 2.0E20/cm3) polysilicon or amorphous silicon. A dilute HF etch for 1 minute in dilute HF (100:1 by volume of H2O:HF) should be done before sputter deposition. This is followed by an RTA step at 700C to 800C in nitrogen or argon for 30 to 40 seconds forming the refractory metal silicide layer 122 which would eventually form the floating gate 122 and the tip 36. The anneal step will transform all polysilicon or amorphous silicon in to a refractory metal silicide. Any remaining unreacted metal should be removed by a mixture of DI water. 30% hydrogen peroxide and ammonium hydroxide (5:1:1) kept at room temperature. A conventional shallow trench isolation process module processing follows. This shallow trench isolation process module forms the isolation between rows columns of memory cells 110. A layer of sacrificial dielectric film is deposited on the structure. The dielectric film is silicon nitride having a thickness of 4000A. This can be formed by LPCVD by reacting silane or dichlorosilane with ammonia at temperatures between 700C and 800C. A photoresist coating and mask exposure follows. The photoresist is developed and is used to etch the sacrificial dielectric in portions not covered by the photoresist coating. The resultant cross-sectional view is shown in FIG. 4a.

Using the sacrificial layer of dielectric as a mask layer, the refractory metal silicide 36 is slope etched. Fluorine based gases such as C2F6, CHF3, SF6, CF4 individually or combination of two or more gases can be used as plasma etch gases. Fluorine etches suicides isotropically. Plasma etch process optimization is required in order to get correct profile After the refractory metal silicide layer 36 is etched, the resultant cross-sectional view is shown in FIG. 4b.

Spacer oxide is deposited everywhere followed by RIE etch back of the spacer oxide to form spacers adjacent to the sacrificial layer. The resultant structure is shown in FIG. 4c. Using the oxide spacer as a mask, the refractory silicide layer 122 is etched using RIE or other anisotropic etch method. The resultant cross-sectional view is shown in FIG. 4d.

A thin layer of thermal oxide is then grown to a thickness of approximately 50A by rapid thermal oxidation at 950C for 40 to 50 seconds in an oxygen ambient. A thin layer of silicon dioxide of the order of 150A is deposited by LPCVD. The layer of deposited oxide is anisotropically etched resulting in oxide spacers being formed adjacent to the refractory silicide layer 22. The resultant structure is shown in FIG. 4e.

Implants are made to form the source region 16. This is done by a combination of arsenic and phosphorus implants. This is followed by an anneal process for the implants. The anneal is done at 900C for 30 minutes in nitrogen. This is followed by HF preclean, which is 1 minute etch in dilute HF (100:1 by volume of H2O:HF). In-situ doped source poly 30 is then etched back. The resultant structure is shown in FIG. 4f.

The source poly is then oxidized. The sacrificial dielectric film first deposited and shown in FIG. 4a is then stripped in hot phosphoric acid mainitained at 80 to 100C. The refractory metal silicide layer forming the floating gate 122 is then etched. A thin thermal oxide is then grown. A tunnel oxide 32 is then deposited by CVD. This is followed by tunnel oxide densification. The word line poly is then deposited by CVD of polysilicon. The word line poly is then implanted with phosphorus and is annealed. The word line spacer is then etched back. A bit line junction implant mask is is used to do bit line junction implant. The resist is stripped and then the structure is annealed. The resultant structure is shown in FIG. 4g.

Referring to FIG. 5, there is a cross-sectional view of a stack gate memory cell 11 of the present invention. The stack gate memory cell 11 is very similar to the split gate memory cell 10 shown in FIG. 1. In particular, the stack gate memory cell 11 has a substrate 12 separates first and second regions 14 and 16 that are of one conductivity type (N+) separated by a channel region 20 of a second conductivity type (p-type). Positioned above the coupling oxide 28 is a floating gate 22. Thus, the floating gate 22 is insulated from the drain 14, channel 20, and the source 16, by the coupling oxide layer 28. The floating gate 22 comprises polysilicon or amorphous silicon with a layer of refractory metal silicide 36 immediately contiguous to and adjacent to the coupling oxide 28. The metal silicide region 36 of the floating gate 22 is on the order of 150 to 200 angstroms. Above the floating gate 22 is another dielectric 32 such as ONO. Finally, a control gate 24, made of polysilicon, is above the ONO region 32.

In operation, the floating gate is programmed by hot channel electrons injected from the channel near the drain into the composite floating gates 22 (polysilicon or amorphosu silicon) and 36 (refractory metal silicide). The electron injection in to the floating gate is caused by the application of high voltage to the control gate 24. The high control gate voltage is coupled to the floating gate 22. The erasure of the floating gate 22 or the removal of stored electrons from the floating gate 22 can occur by one of several mechanisms. The stored electrons can flow by Fowler-Nordheim tunneling mechanism from the floating gate 22 into the channel region 20 when a high voltage is applied to the substrate 12 or to the source region 16 when high voltage is applied to the source region 16. In either event, the Fowler-Nordheim tunneling mechanism causes electrons to tunnel through the coupling oxide 28.

One example to manufacture the memory cell 11 is as follows.

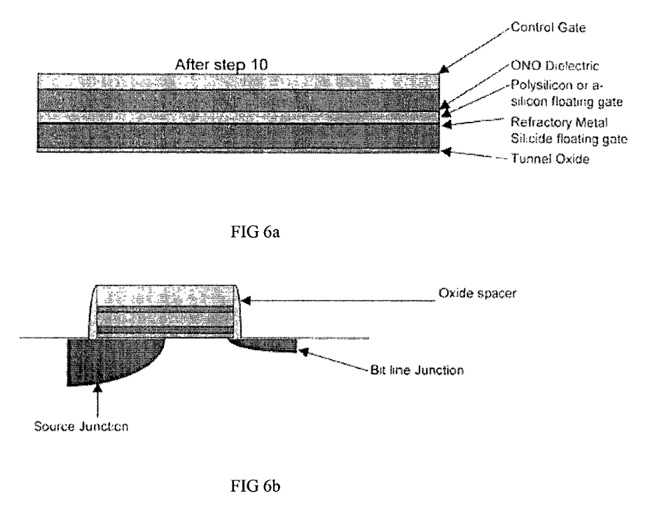

A substrate 12 which is of P type is the initial starting material. The first step is The first step is removal of native oxide by etching in buffered HF (NH4F+HF+H2) with surfactants followed by RCA clean of a p-type substrate 12. A conventional shallow trench isolation process module processing follows. This shallow trench isolation process module forms the isolation between columns of memory cells 11. The tunnel oxide layer 28 is thermally grown on the substrate 12 to a thickness of approximately 80A. A thin layer 36, on the order of 150A to 200A in thickness of refractory metal suicide is deposited by CVD or sputtering from a refractory metal silicide layer target. This is followed by polysilicon or amorphous silicon deposition forming the floating gate 22. The floating gate 22 formed is on the order of 600A to 650A, in thickness. The floating gate 22 is then doped by arsenic or phosphorus implant of dose 1.0E15 to 2.0E15/cm2 at 3 KeV. The implant is then annealed. An ONO dielectric stack 32 is then formed. This can be done by CVD, forming the silicon (di) dioxide layer first using diluted thermal oxidation, followed by the silicon nitride layer deposited by LPCVD, and then followed by the silicon dioxide growth by pyrogenic oxidation. Total thickness of composite ONO layer can be between 100A and 150A. A layer of approximately 2000 to 2500A in thickness of polysilicon is deposited to form the control gate 24. The control gate 24 is then doped by an arsenic implant of 3.0E15 to 5.0E15/cm2 at 10 to 15 KeV. The implant is then annealed. The resultant structure is shown in FIG. 6a.

A photoresist is then formed over the structure shown in FIG. 6a. The photoresist is subject to a mask operation, and then an etch operation performed to remove the portions of the stack that does not constitute the memory cell 11. The photoresist is then removed. A thermal oxidation step is then performed. This step causes all of the exposed polysilicon of the control gate 24, and along the side wall of the composite floating gate 22 and 36, to be oxidized. A spacer oxide layer is then deposited over the structure. This can be done by LPCVD forming a layer of approximately 300A to 400A in thickness. The spacer oxide layer is then anisotropically etched resulting in spacer oxides being formed along the sides of the “stack” of the memory cell 11. This is followed by a photoresist masking operation followed by combination of arsenic and phosphorus implants which form the source. Source implants have doses of approximately 1.0E15/cm2 to 3.0E15/cm2 at approximately 20 to 25 KeV. Photoresist is stripped and the structure is annealed for driving the source implants deeper into the substrate 12. Another masking operation using photoresist is again applied to define the bitline (or drain) regions 14. The photoresist is exposed, and the bitline regions 14 are exposed. This is followed by bitline implant (arsenic) with a dose of approximately 3.0E15/cm2 at 10 to 20 KeV. The photoresist is stripped. The structure is annealed to activate and drive in the bitline junction implants into the substrate 12. The structure is reoxidized. The resulting structure is shown in FIG. 6b. With the exception of the formation of the metal silicide layer 36 all of the steps to form the memory cell 11 are well known in the art.

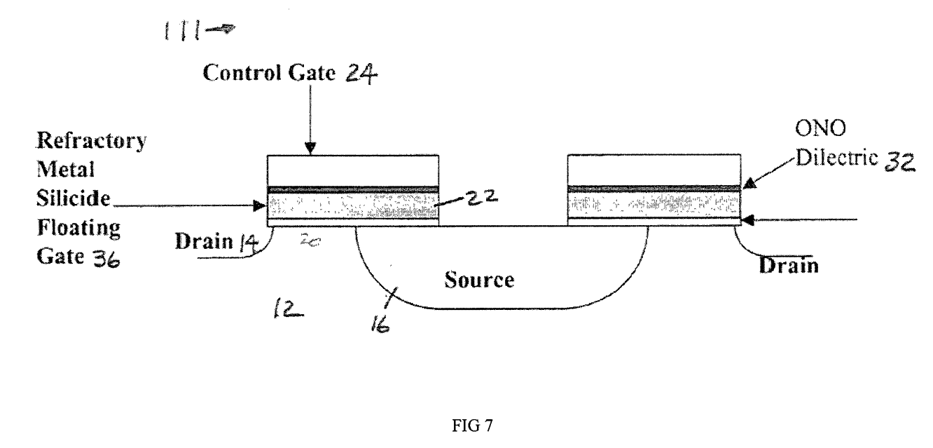

Referring to FIG. 7, there is shown a cross-sectional view of another embodiment of a stack gate memory cell 111 with the present invention. The memory cell 111 is similar to the memory cell 11 shown in FIG. 5. The only difference is that the floating gate 22 is now made entirely of a metal silicide material. Again, similar to the memory cell 11, the mechanism or program is done by hot channel electron injection from the channel near the drain 14 through the coupling gate oxide 28 onto the floating gate 22. The mechanism of erasure of the floating gate 22 is through a Fowler-Nordheim tunnel of electrons from the floating gate 22 to either the channel region 20 or to the source 16.

A method to manufacture the memory cell 111 is as follows:

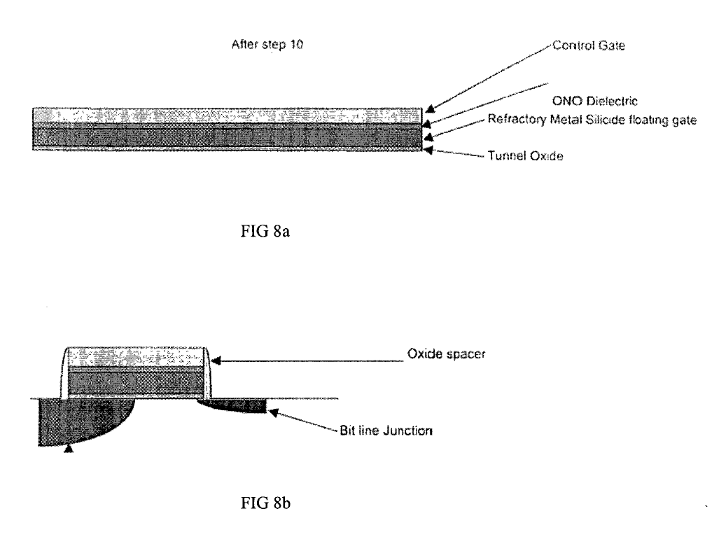

A substrate 12 which is of P type is the initial starting material. The first step is The first step is removal of native oxide by etching in buffered HF (NH4F+HF+H2) followed by RCA clean of a the p-type substrate 12. A conventional shallow trench isolation process module processing follows. This shallow trench isolation process module forms the isolation between columns of memory cells 111. The tunnel oxide layer 28 is thermally grown on the substrate 12 to a thickness of approximately 80A. A layer 22, on the order of 800A in thickness of refractory metal silicide is formed by CVD or sputtering from refractory metal silicide target, which eventually forms the floating gate 22. An ONO dielectric stack 32 is then formed. This can be done by CVD, forming the silicon dioxide layer first using diluted thermal oxidation, followed by the silicon nitride layer deposited by LPCVD, and then followed by the silicon dioxide growth by pyrogenic oxidation. Total thickness of composite ONO layer can be between 100A and 150A. A layer of approximately 2000 to 2500A in thickness of polysilicon is deposited to form the control gate 24. The control gate 24 is then doped by arsenic implant of 3.0E15 to 5.0E15/cm2 at 10 to 15 KeV. The implant is then annealed. The resultant structure is shown in FIG. 8a.

A photoresist is then formed over the structure shown in FIG. 8a. The photoresist is subject to a mask operation, and then an etch operation is performed to remove the portions of the stack that does not constitute the memory cell 111. The photoresist is then removed. A thermal oxidation step is then performed. This step causes all of the exposed polysilicon of the control gate 24, and along the side wall of the refractory metal silicide floating gate 122, to be oxidized. A spacer oxide layer is then deposited over the structure. This can be done by LPCVD forming a layer of approximately 300A to 400A formed over the structure. The spacer oxide layer is then anisotropically etched resulting in spacer oxides being formed along the sides of the “stack” of the memory cell 111. This is followed by a photoresist masking operation followed by combination of arsenic and phosphorus implants which form the source. Source implants have doses of approximately 1.0E15/cm2 to 3.0E15/cm2 at approximately 20 to 25 KeV. The photoresist is stripped and the structure is annealed for driving the source implants deeper into the substrate 12. Another masking operation using photoresist is again applied to define the bitline (or drain) regions 14. The photoresist is exposed, and the bitline regions 14 are exposed. This is followed by a second bitline implant (arsenic) with a dose of approximately 3.0E15/cm2 at 10 to 20 KeV. The photoresist is stripped. The structure is annealed to activate and drive in the bitline junction implants into the substrate 12. The structure is reoxidized. The resulting structure is shown in FIG. 8b. With the exception of the formation of the metal silicide floating gate 22 all of the steps to form the memory cell 111 are well known in the art. Process temperatures cannot exceed 950C for titanium and cobalt suicides and 1000C for tungsten and tantalum silicides after the formation of siliedes.

The theory of the present invention is as follows. It should be noted that the model presented here is of the first order, planar electrodes between thin oxide are assumed and there are no traps to begin with in the thin oxide. When it is desired to move electrons through the mechanism of Fowler-Nordheim tunneling from a first region, through an insulating material to a second region, the erase efficiency can be improved if the Fermi level in the first material (i.e., refractory metal silicide) is closer to the conduction band. Then in equilibrium, without applied voltages, the Fermi level of the second material (i.e., polysilicon wordline) will be at the same level as that of the first material. This decreases the barrier height of the insulating material. In particular, the properties of the doped polysilicon are as follows:

| Typical Resistivity | 500 μOhm-cm |
|---|---|
| Electron concentration (n) | 1.67E19/cm3 |
| (assuming electron mobility of 750 cm²/V-sec in poly*) | |
| Fermi Level from mid band gap | 0.542eV* |
| Fermi Level from conduction band | 0.076eV* |

*Band gap of polysilicon = 1.24eV, Electron mobility = 750 cm2/V-sec (From: Ted Kamins: Polycrystalline Silicon for IC Applications)

However, for a refractory metal silicide material, the properties for that are as follows.

| | |
|---|---|
| Typical Resistivity | 15 μOhm-cm(for Cobalt Silicide) |
| Electron concentration (n) | 5.56E20/cm3 |

(Electron mobility of 750 cm2/V-sec* in silicide)

| | |
|---|---|
| Fermi Level from mid band gap | 0.634eV |
| Fermi Level from conduction band | ˜0.0eV |

As can be seen from the foregoing the difference in the Fermi level from the conduction band between polysilicon and refractory metal silicide is approximately 0.076 ev. Thus, the free electron energy level is higher in the refractory metal silicide region thereby lowering the oxide barrier by approximately 0.076 ev when it traverses the insulating region. This can be seen from the following equations.

Work Function (φ)=χ+Eg/2−ψ_{b}

where

ψ=Electron Affinity, Eg=Band Gap, ψ_{b}=Fermi Level to Mid gap

φ=4.05+0.62−0.544=4.126 eV for Poly/oxide/Poly system

φ=4.05+0.62−0.620=4.05 eV for Silicide/oxide/Poly system

Oxide barrier height is lowerd by 0.076 eV by using refractory metal silicide as floating gate tip or floating gate material. In addition, however, Fowler-Nordheim Current Density Equation is determined by:

J=AE²exp(-B/E)

Where J=Current density, E is electric field across oxide A and B are constants.

A and slope B are related to barrier height by:

A=(Constant)/φ

B=(Constant)*(φ)¹⁵

A=1.57*10⁻⁶ Amps/V² B=2.8*10⁸ V/cm for poly/oxide/poly

A=1.60*10⁻⁶ Amps/V² B=2.57*10⁸ V/cm for poly/oxide/poly

Fowler-Nordheim current density for oxide thickness of 150A and voltage difference of 11V between floating gate and wordline is

J(P/O/P)=5.09*10⁻⁸ Amps/cm2

J(S/O/P)=1.54*10−⁷ Amps/cm2

As a result, for the same Fowler-Nordheim tunneling mechanism between polysilicon/oxide/polysilicon scheme to metal silicide/oxide/polysilicon scheme, the applied voltage can be approximately 0.7 volt lower to create the same amount of Fowler-Nordheim current density. This result can be seen in FIG. 9 wherein for a poly/oxide/poly tunnel mechanism, approximately 0.7 higher voltage must be applied to achieve the same current density flow as for a silicide/oxide/poly system. Alternatively, if one were to apply the same voltage between the two schemes, i.e., the same voltage were applied to a poly/oxide/poly system versus a silicide/oxide/poly system, a higher current density would result in a silicide/oxide/poly system. This results in a faster erase mechanism. Thus, the benefit of the present invention is either the voltage applied for erase can be lowered which decreases the need for a high voltage charge pump and the attendant beneficial result of less high voltage isolation is required, or the same charge pump as in the prior art can be maintained resulting in faster erasure time. Effect of using refractory metal silicides as a floating gate material in split gate flash cells of FIGS. 1 and 2 on read disturb and data retention should be evaluated. Similarly, in stack gate flash memory cells of FIGS. 3 and 4, increased hole injection (holes generated during erasre due to band to band tunneling) through tunnel oxide can cause endurance degradation. Also effect on data retention should be studied.

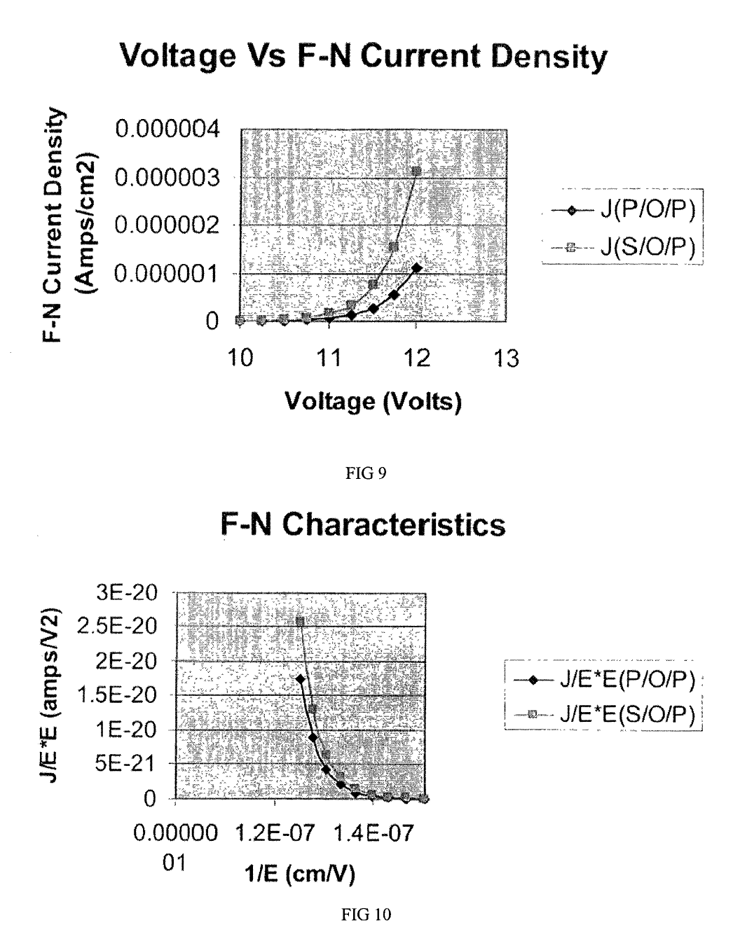

Referring to FIG. 10, there is shown a chart of the calculated Fowler-Nordheim characteristics between a poly/oxide/poly system versus a silicide/oxide/poly system.

What is claimed is:

1. A non-volatile memory cell comprising:
a semiconductor substrate;
a first and second regions of a first conductivity type in said substrate; wherein said first and second regions are spaced apart by a channel region of a second conductivity type;
a floating gate insulated from said substrate and positioned adjacent to a first portion of said channel and to a portion of said first region;
a first insulation layer for providing insulation between said substrate and said floating gate;
a control gate insulated from said substrate and from said floating gate and positioned adjacent to said floating gate, and adjacent to a second portion of said channel and to a portion of said second region;
a second insulation layer for providing insulation between said control gate and said floating gate, wherein said second insulation layer having a dimension permitting the Fowler-Nordheim tunneling of electrons from said floating gate to said control gate; and
wherein said floating gate further having a tip for facilitating the tunneling of electrons to said control gate, said tip being a metal silicide.

2. The cell of claim 1 wherein said metal silicide is a refractory metal silicide.

3. The cell of claim 1 wherein all of said floating gate is of a metal silicide compound.

4. The cell of claim 3 wherein said metal silicide is a refractory metal silicide.

5. The cell of claim 1 wherein said first insulation layer having a dimension permitting the injection of electrons by hot electron injection from said substrate therethrough to said floating gate.

6. A non-volatile memory cell comprising:
a semiconductor substrate;
a first and second regions of a first conductivity type in said substrate; wherein said first and second regions are spaced apart by a channel region of a second conductivity type;
a floating gate insulated from said substrate and positioned adjacent to a portion of said channel and to a portion of said first region;
a first insulation layer for providing insulation between said substrate and said floating gate, wherein said first insulation layer having a dimension permitting the Fowler-Nordheim tunneling of electrons from said floating gate to said substrate;
a control gate insulated from said floating gate;
a second insulation layer for providing insulation between said floating gate and said control gate; and
wherein said floating gate further having a metal silicide region immediately contiguous and adjacent to said first insulation layer for facilitating the tunneling of electrons to said substrate.

7. The cell of claim 6 wherein said first insulation layer facilitates the tunneling of electrons to said channel region.

8. The cell of claim 6 wherein said first insulation layer facilitates the tunneling of electrons to said first region.

9. The cell of claim 6 wherein all of said floating gate is of a metal silicide compound.

10. A method of improving erase efficiency in a non-volatile memory cell between a floating gate from which electrons are to be removed through an insulating material to a region in said cell thereby erasing said floating gate, said region being of a first material having a first work function, wherein said method comprising:
providing a second material having a second work function, lower than said first work function, before the two materials are joined together, to said floating gate immediately adjacent to said insulating material, said second material being a material from which electrons from said floating gate traverse through said insulating material to said region.

11. The method of claim 10 wherein said first material is a material selected from single crystalline silicon, polysilicon and amorphous silicon.

12. The method of claim 11 wherein said second material is a refractory metal silicide.

13. The method of claim 12 wherein said insulating material is silicon dioxide.

14. The method of claim 12 wherein the entire floating gate is of said second material.

15. A non-volatile semiconductor memory cell having a floating gate in which electrons are stored, and from which electrons are removed through an insulating material to a region in said cell, thereby erasing said floating gate, said region being of a first material having a first work function, wherein said improvement comprising:
said floating gate having a second material having a second work function lower than said first work function, before the materials are joined together, positioned immediately adjacent to said insulating material, said second material being a material from which electrons from said floating gate traverse through said insulating material to said region.

16. The cell of claim 15 wherein said first material is a material selected from single crystalline silicon, polysilicon, and amorphous silicon.

17. The cell of claim 16 wherein said second material is a refreactory metal silicide.

18. The cell of claim 17 wherein said insulating material is silicon (di)oxide.
